(19) United States
(12) Patent Application Publication
(10) Pub. No.: US 2012/0012864 A1
(43) Pub. Date: Jan. 19, 2012

(54) LED ARRAY PACKAGE WITH A COLOR FILTER

(76) Inventors: Suning Xie, Livermore, CA (US); Jianhua Li, Livermore, CA (US); Chao-Kun Lin, Livermore, CA (US)

(21) Appl. No.: 12/836,140

(22) Filed: Jul. 14, 2010

(51) Int. Cl. H01L 33/58

(52) U.S. Cl. 257/88; 257/E33.067

(57) ABSTRACT

A light source includes a substrate, a light emitting diode on the substrate within a cavity, a plate over the cavity, a phosphor layer on the plate, and a color filter on the plate between the phosphor layer and the cavity.

### BACKGROUND

1. Field

The present disclosure relates to a light emitting diode (LED) array package and, more particularly, to an LED array package with a color filter.

2. Description of Related Art

LEDs have been developed for many years and have been widely used in various light applications. As LEDs are light-weight, consume less energy, and have a good electrical power to light conversion efficiency, they have been used to replace conventional light sources, such as incandescent lamps and fluorescent light sources. LEDs may be utilized in an array package. There is a current need in the art for improving the efficiency and light output of LED array packages.

### SUMMARY

In an aspect of the disclosure, a light source includes a substrate, a light emitting diode on the substrate within a cavity, a plate over the cavity, a phosphor layer on the plate, and a color filter on the plate between the phosphor layer and the cavity.

In an aspect of the disclosure, a light source includes a substrate, a light emitting diode on the substrate within a cavity, a plate over the cavity, a phosphor layer on the plate, and means for filtering light. The means for filtering light is between the phosphor layer and the cavity and is configured to transmit light emitted from the light emitting diode and reflect light emitted from the phosphor layer.

### BRIEF DESCRIPTION OF THE DRAWINGS

FIG. 1 is a cross-section view of a first exemplary LED array package.

FIG. 2A is a cross-section view of a second exemplary LED array package.

FIG. 2B is a cross-section view of a third exemplary LED array package.

FIG. 3 is a cross-section view of a fourth exemplary LED array package.

FIG. 4A is a cross-section view of a fifth exemplary LED array package.

FIG. 4B is a cross-section view of a sixth exemplary LED array package.

### DETAILED DESCRIPTION

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element. In addition, when a first element is “coupled” to a second element, the first element may be directly connected to the second element or the first element may be indirectly connected to the second element with intervening elements between the first and second elements.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can therefore encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of an. LED array package may be illustrated with reference to one or more exemplary configurations. As used herein, the term “exemplary” means “serving as an example, instance, or illustration,” and should not necessarily be construed as preferred or advantageous over other configurations of an LED array package disclosed herein. Furthermore, various descriptive terms used herein, such as “on” and “transparent,” should be given the broadest meaning possible within the context of the present disclosure. For example, when a layer is said to be “on” another layer, it should be understood that that one layer may be deposited, etched, attached, or otherwise prepared or fabricated directly or indirectly above or below that other layer. In addition, something that is described as being “transparent” should be understood as having a property allowing no significant obstruction or absorption of electromagnetic radiation in the particular wavelength (or wavelengths) of interest, unless a particular transmittance is provided.

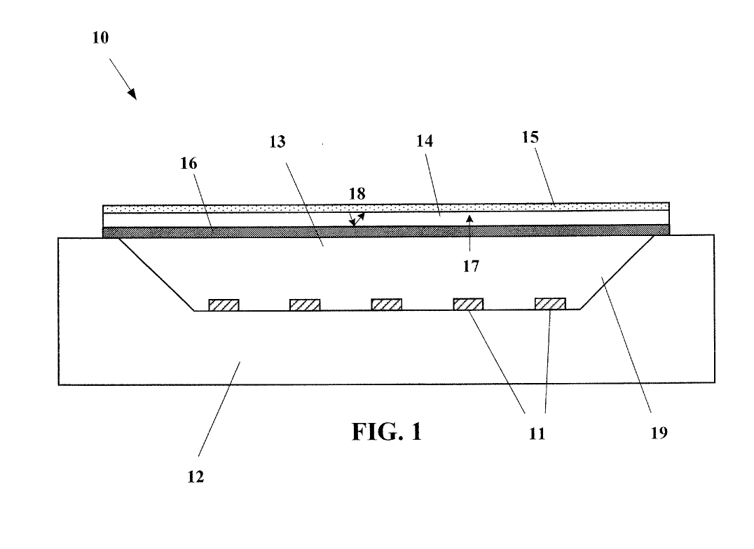

FIG. 1 is a cross-section view of a first exemplary LED array package 10. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes. A doped region with electrons may be referred to as an n-type semiconductor region. A doped region with holes may be referred to as a p-type semiconductor region. In LED applications, the semiconductor includes an n-type semiconductor region, a p-type semiconductor region, and an intervening active region between the n-type and p-type semiconductor regions. When a forward voltage sufficient to overcome the reverse electric field is applied across the p-n junction, electrons and holes are forced into the active region and combine. When electrons combine with holes, they fall to lower energy levels and release energy in the form of light.

The light source may be configured to produce white light. White light may enable the light source to act as a direct replacement for conventional light sources used today in incandescent and fluorescent light sources. There are at least two common ways for producing white light. One way is to use individual LEDs that emit red, green, and blue, and then mix all the colors to produce white light. Another way is to use a phosphor material to convert monochromatic light emitted from a blue or ultra-violet (UV) LED to broad-spectrum white light. The present invention, however, may be practiced with other LED and phosphor combinations to produce different color light.

As shown in FIG. 1, an array of LEDs 11 is on substrate 12 within a cavity 19 in the substrate 12. The LEDs 11 may emit blue light. The array of LEDs 11 may be covered with a layer of silicone 13 within the cavity 19. A phosphor layer 15 is coated on one side of a plate 14. A color filter 16 is coated or otherwise located on the other side of the plate 14. The plate 14 may be transparent with a high thermal conductivity. More specifically, the plate 14 may be a sapphire plate, a silicon carbide (SiC) plate, a chemical-vapor-deposition (CVD) diamond plate, CVD SiC on a glass plate, CVD diamond on a glass plate, a glass plate, a zinc oxide (ZnO) plate, a quartz crystal plate, or any of the aforementioned types of plates with a metal net as described in U.S. patent application Ser. No. 12/487453, entitled “LED Array Package Covered with a Highly Thermal Conductive Plate” and which is herein incorporated by reference. The phosphor and color filter plate 14, 15, 16 is then attached on top of the substrate 12 and silicone layer 13. That is, the phosphor and color filter plate 14, 15, 16 may be attached or otherwise cured to at least one of the silicone layer 13 or the substrate 12. The color filter 16 may include a single layer film coating or multiple layers of film coating on plate 14 to achieve a high transmission for blue light 17 emitted from the LEDs 11 and a high reflectivity for yellow and/or red light 18 emitted from the phosphor layer 15 in order to improve the overall white light emission efficiency and total light output of the LED array package 10.

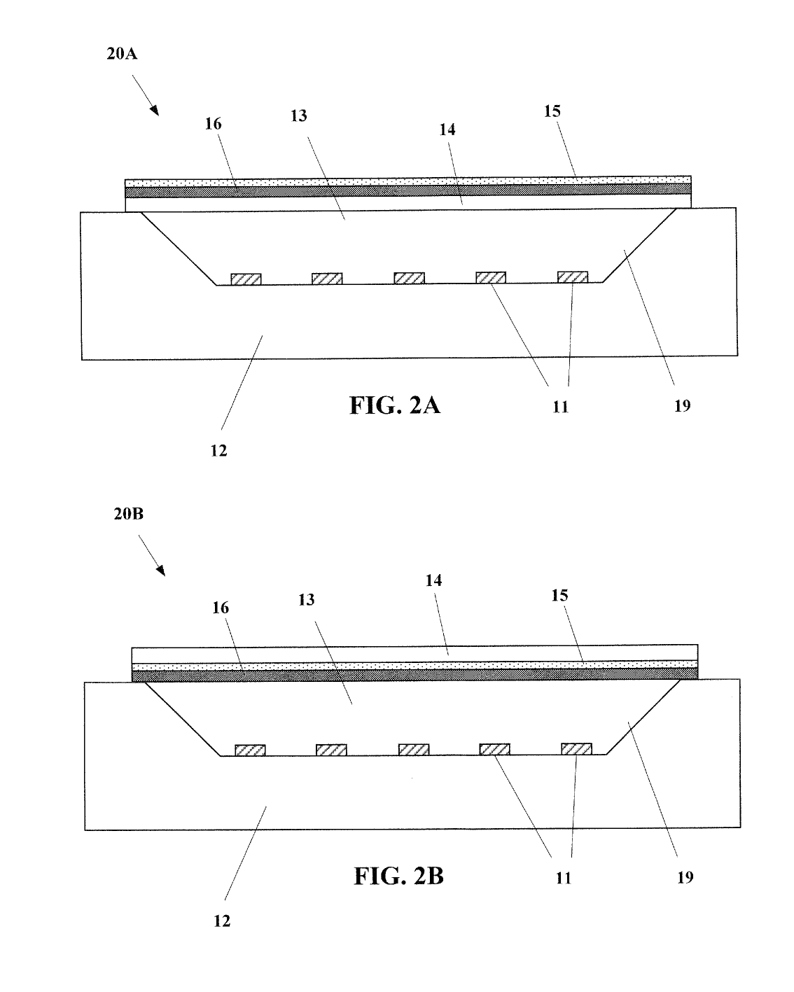

FIG. 2A is a cross-section view of a second exemplary LED array package 20A. FIG. 2B is a cross-section view of a third exemplary LED array package 20B. As shown in FIG. 2A, the phosphor layer 15 is on the plate 14 opposite the cavity 19 and the color filter 16 is on the plate 14 between the plate 14 and the phosphor layer 15. As shown in FIG. 2B, the phosphor layer 15 is on the plate 14 between the plate 14 and the cavity 19 and the color filter 16 is on the plate 14 between the phosphor layer 15 and the cavity 19.

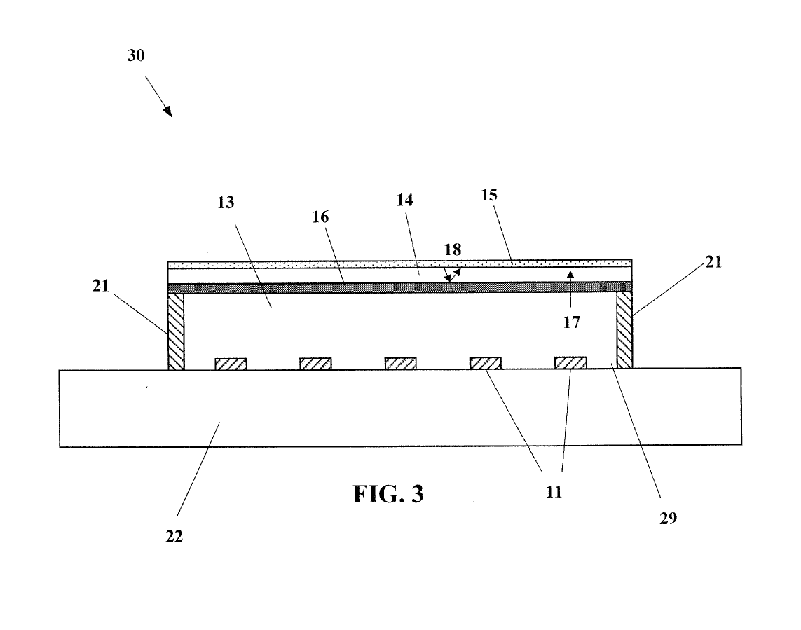

FIG. 3 is a cross-section view of a fourth exemplary LED array package 30. As shown in FIG. 3, an array of LEDs 11 is on the substrate 22. A plate supporting member 21 is attached to the substrate 22 and surrounds the array of LEDs 11 to form a cavity 29 around the LEDs 11. The plate supporting member 21 may be a ring-shaped vertical member that extends approximately perpendicular to the substrate 22. The ring 21 may be thermally conductive and formed of metal. Alternatively, the ring 21 may be thermally resistive and formed of silicon. When the ring is formed of silicon or is otherwise thermally resistive, the ring 21 has a height such that the silicone layer 13 is sufficiently thin as described in U.S. patent application entitled “LED Array Package with a High Thermally Conductive Plate” by inventors Jianhua Li, Rene Helbing, and David Hum and which is herein incorporated by reference. Clear silicone 13 is dispensed within the cavity 29 formed by the ring 21. Phosphor 15 is layered onto one side of a plate 14 and a color filter 16 is coated, layered, or otherwise located on the other side of the plate 14. The phosphor and color coated plate 14 is located on top of the clear silicone 13 and the ring 21. The phosphor and color coated plate 14, 15, 16 may be attached to the ring 21 or otherwise cured to at least one of the silicone layer 13 or the ring 21. The color filter 16 transmits blue light 17 emitted from the LEDs 11 and reflects yellow and/or red light 18 emitted from the phosphor layer 15. The color filter 16 improves the light emission efficiency and total light output because the blue light 17 emitted from the LEDs 11 is transmitted through the color filter 16, and the yellow and/or red light 18, which is emitted by the phosphor layer 15, is reflected directly back to the phosphor layer 15 without hitting the substrate 12. As described supra, the color filter 16 may include a single layer film coating or multiple layers of film coating to achieve a high transmission for blue light 17 emitted from the LEDs 11 and a high reflectivity for yellow and/or red light 18 in order to improve the overall light emission efficiency and total light output of the LED array package 30.

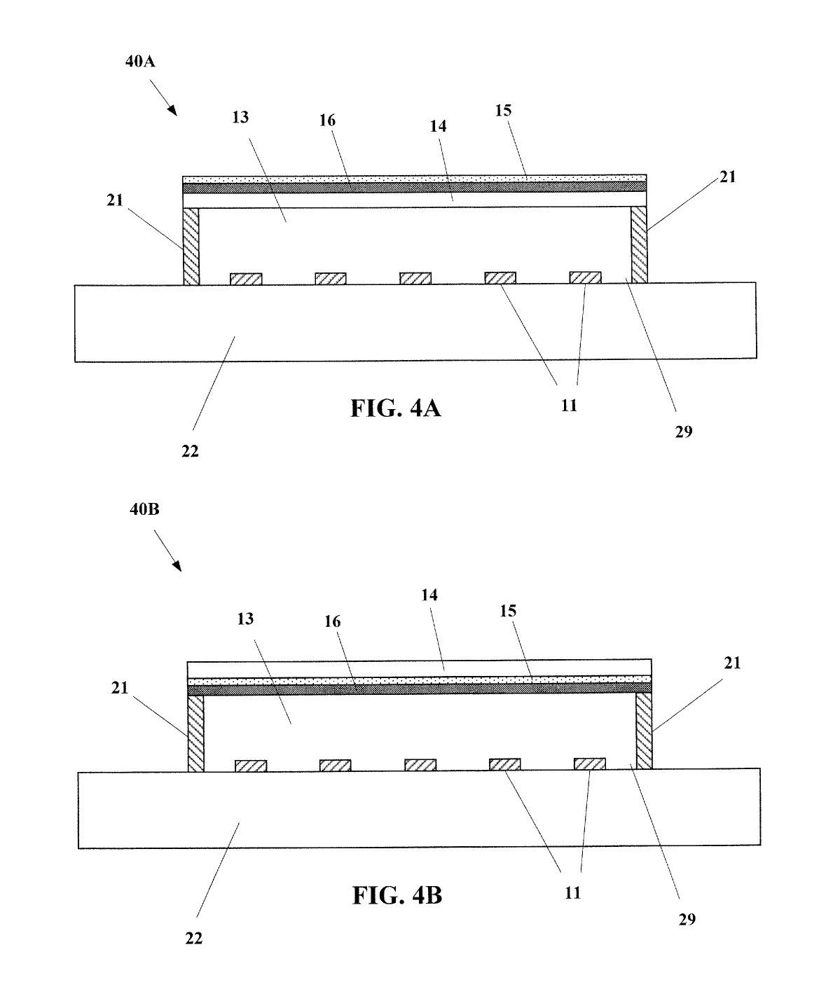

FIG. 4A is a cross-section view of a fifth exemplary LED array package 40A. FIG. 4B is a cross-section view of a sixth exemplary LED array package 40B. As shown in FIG. 4A, the phosphor layer 15 is on the plate 14 opposite the cavity 19 and the color filter 16 is on the plate 14 between the plate 14 and the phosphor layer 15. As shown in FIG. 4B, the phosphor layer 15 is on the plate 14 between the plate 14 and the cavity 19 and the color filter 16 is on the plate 14 between the phosphor layer 15 and the cavity 19.

Referring again to FIGS. 1 through 4B, a light source may include a substrate, a light emitting diode on the substrate within a cavity, a plate over the cavity, a phosphor layer on the plate, and a means for filtering light. The means for filtering light is between the phosphor layer and the cavity and is configured to transmit light emitted from the light emitting diode and reflect light emitted from the phosphor layer. The means for filtering light may be a color filter that is layered, coated, or otherwise located between the phosphor layer and the cavity. The color filter may include a single layer film coating or multiple layers of film coating in order to transmit light emitted from the light emitting diode and reflect light emitted by the phosphor layer.

While it has been described supra that the LEDs 11 emit blue light and the color filter 16 transmits blue light and reflects yellow and/or red light, more generally, the LEDs 11 may emit light with wavelengths in a first set and the phosphor layer may emit light with wavelengths in a second set. The color filter 16 is configured to transmit light emitted by the LEDs 11 with wavelengths in at least a subset of the first set and to reflect light with wavelengths in at least a subset of the second set. The first set may include wavelengths categorized as blue light, which include wavelengths between around 445 nm and 465 nm. The second set may include wavelengths categorized as yellow and/or red light, which include wavelengths between around 560 nm to 750 nm.

The various aspects of this disclosure are provided to enable one of ordinary skill in the art to practice the present invention. Modifications to various aspects of an LED array package presented throughout this disclosure will be readily apparent to those skilled in the art, and the concepts disclosed herein may be extended to other applications. Thus, the claims are not intended to be limited to the various aspects of an LED array package presented throughout this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A light source, comprising:
a substrate;
a light emitting diode on the substrate within a cavity;
a plate over the cavity;
a phosphor layer on the plate; and
a color filter on the plate between the phosphor layer and the cavity.

2. The light source of claim 1, wherein the phosphor layer is on the plate opposite the cavity and the color filter is on the plate between the plate and the cavity.

3. The light source of claim 1, wherein the phosphor layer is on the plate opposite the cavity and the color filter is on the plate between the plate and the phosphor layer.

4. The light source of claim 1, wherein the phosphor layer is on the plate between the plate and the cavity and the color filter is on the plate between the phosphor layer and the cavity.

5. The light source of claim 1, wherein the color filter transmits blue light from the light emitting diode and reflects at least one of yellow or red light from the phosphor layer.

6. The light source of claim 1, wherein the plate, the color filter, and the phosphor layer are attached to a top surface of the substrate.

7. The light source of claim 1, further comprising a plate supporting member attached to the substrate and surrounding the light emitting diode to form the cavity.

8. The light source of claim 7, wherein the plate, the color filter, and the phosphor layer are attached to a top surface of the plate supporting member.

9. The light source of claim 7, wherein the plate supporting member is metal.

10. The light source of claim 7, wherein the plate supporting member is silicon.

11. The light source of claim 7, wherein the plate supporting member comprises a ring-shaped vertical member extending approximately perpendicular to the substrate.

12. The light source of claim 7, further comprising a silicone layer over the light emitting diode within the cavity.

13. The light source of claim 12, wherein the plate, the color filter, and the phosphor layer are cured to at least one of the silicone layer or the plate supporting member.

14. The light source of claim 1, further comprising a silicone layer over the light emitting diode within the cavity.

15. The light source of claim 14, wherein the plate, the color filter, and the phosphor layer are cured to at least one of the silicone layer or the substrate.

16. The light source of claim 1, wherein the plate is transparent.

17. The light source of claim 1, wherein the plate is a sapphire plate, a silicon carbide plate, a chemical-vapor-deposition diamond plate, chemical-vapor-deposition silicon carbide on a glass plate, chemical-vapor-deposition diamond on a glass plate, a glass plate, a zinc oxide plate, or a quartz crystal plate.

18. The light source of claim 1, further comprising at least one additional light emitting diode on the substrate, wherein said light emitting diode and said at least one additional light emitting diode are in an array on the substrate.

19. The light source of claim 18, wherein the light emitting diode and the one additional light emitting diode emit blue light.

20. A light source, comprising:
a substrate;
a light emitting diode on the substrate within a cavity;
a plate over the cavity;
a phosphor layer on the plate; and
a means for filtering light, the means for filtering light being between the phosphor layer and the cavity and being configured to transmit light emitted from the light emitting diode and reflect light emitted from the phosphor layer.

21. The light source of claim 20, wherein the phosphor layer is on the plate opposite the cavity and the means for filtering light is on the plate between the plate and the cavity.

22. The light source of claim 20, wherein the phosphor layer is on the plate opposite the cavity and the means for filtering light is on the plate between the plate and the phosphor layer.

23. The light source of claim 20, wherein the phosphor layer is on the plate between the plate and the cavity and the means for filtering light is on the plate between the phosphor layer and the cavity.

24. The light source of claim 20, wherein the means for filtering light transmits blue light from the light emitting diode and reflects at least one of yellow or red light from the phosphor layer.

25. The light source of claim 20, wherein the plate, the means for filtering light, and the phosphor layer are attached to a top surface of the substrate.

26. The light source of claim 20, further comprising a plate supporting member attached to the substrate and surrounding the light emitting diode to form the cavity.

27. The light source of claim 26, wherein the plate, the means for filtering light, and the phosphor layer are attached to a top surface of the plate supporting member.

28. The light source of claim 26, wherein the plate supporting member is metal.

29. The light source of claim 26, wherein the plate supporting member is silicon.

30. The light source of claim 26, wherein the plate supporting member comprises a ring-shaped vertical member extending approximately perpendicular to the substrate.

31. The light source of claim 26, further comprising a silicone layer over the light emitting diode within the cavity.

32. The light source of claim 31, wherein the plate, the means for filtering light, and the phosphor layer are cured to at least one of the silicone layer or the plate supporting member.

33. The light source of claim 20, further comprising a silicone layer over the light emitting diode within the cavity.

34. The light source of claim 33, wherein the plate, the means for filtering light, and the phosphor layer are cured to at least one of the silicone layer or the substrate.

35. The light source of claim 20, wherein the plate is transparent.

36. The light source of claim 20, wherein the plate is a sapphire plate, a silicon carbide plate, a chemical-vapor-deposition diamond plate, chemical-vapor-deposition silicon carbide on a glass plate, chemical-vapor-deposition diamond on a glass plate, a glass plate, a zinc oxide plate, or a quartz crystal plate.

37. The light source of claim 20, further comprising at least one additional light emitting diode on the substrate, wherein said light emitting diode and said at least one additional light emitting diode are in an array on the substrate.

38. The light source of claim 37, wherein the light emitting diode and the one additional light emitting diode emit blue light.
